(19) United States
(12) Patent Application Publication
(10) Pub. No.: US 2025/0385698 A1
(43) Pub. Date: Dec. 18, 2025

(54) AMBIENT IOT DEVICE WITH AMPLIFIER OSCILLATION DETECTION

(71) Applicant: NOKIA TECHNOLOGIES OY, Espoo (FI)

(72) Inventors: Ioannis KIMIONIS, Murray Hill, NJ (US); Johannes HARREBEK, Aalborg (DK); Simon SVENDSEN, Aalborg (DK); Benny VEJLGAARD, Gistrup (DK)

(21) Appl. No.: 19/239,622

(22) Filed: Jun. 16, 2025

(30) Foreign Application Priority Data
Jun. 17, 2024 (GB) 2408659.7

(51) Int. Cl. H04B 1/00; H03F 1/02

(52) U.S. Cl. CPC H04B 1/0078; H03F 1/02; H04B 1/0082

(57) ABSTRACT

The disclosure relates to an apparatus comprising: an antenna configured to receive an activation signal; an amplifier configured to amplify the activation signal; an oscillation detector configured to detect oscillations; a first switch configured to connect directly or indirectly the amplifier to the antenna or connect directly or indirectly the amplifier to the oscillation detector; and means for controlling the first switch to connect directly or indirectly the amplifier to the oscillation detector or to connect directly or indirectly the amplifier to the antenna; means for determining whether oscillations are detected by the oscillation detector; and means for controlling the amplifier based on whether oscillations are detected by the oscillation detector.

### RELATED APPLICATIONS

This application claims priority to United Kingdom patent application No. GB 2408659.7, filed Jun. 17, 2024, entitled “APPARATUS, METHOD, AND COMPUTER PROGRAM” which is hereby incorporated by reference in its entirety.

### FIELD OF THE DISCLOSURE

The present disclosure relates to an apparatus, a method, and a computer program for managing an apparatus (e.g., ambient Internet of things device) in a communication system.

### BACKGROUND

A communication system can be seen as a facility that enables communication sessions between two or more entities such as communication devices, base stations and/or other nodes by providing carriers between the various entities involved in the communications path.

The communication system may be a wireless communication system. Examples of wireless systems comprise public land mobile networks (PLMN) operating based on radio standards such as those provided by 3GPP, satellite based communication systems and different wireless local networks, for example wireless local area networks (WLAN). The wireless systems can typically be divided into cells, and are, therefore, often referred to as cellular systems.

The communication system and associated devices typically operate in accordance with a given standard or specification which sets out what the various entities associated with the system are permitted to do and how that should be achieved. Communication protocols and/or parameters which shall be used for the connection are also typically defined. Examples of standard are 4G, 5G or 6G standards.

### SUMMARY

According to an aspect there is provided an apparatus comprising: an antenna configured to receive an activation signal; an amplifier configured to amplify the activation signal; an oscillation detector configured to detect oscillations; a first switch configured to connect directly or indirectly the amplifier to the antenna or connect directly or indirectly the amplifier to the oscillation detector; means for controlling the first switch to connect directly or indirectly the amplifier to the oscillation detector or to connect directly or indirectly the amplifier to the antenna; means for determining whether oscillations are detected by the oscillation detector; and means for controlling the amplifier based on whether oscillations are detected by the oscillation detector.

The amplifier may be turned on.

The means for determining whether oscillations are detected by the oscillation detector may comprise: means for determining that oscillations are detected by the oscillation detector; and means for controlling the amplifier based on whether oscillations are detected by the oscillation detector comprises: means for determining that a bias of the amplifier is above a minimum bias; and means for controlling the amplifier to reduce the bias of the amplifier.

The means for determining whether oscillations are detected by the oscillation detector may comprise: means for determining that oscillations are detected by the oscillation detector; and means for controlling the amplifier based on whether oscillations are detected by the oscillation detector may comprise: means for determining that a bias of the amplifier is equal to a minimum bias; and means for controlling the amplifier to turn off the amplifier.

The apparatus may comprise: means for modulating the activation signal.

As a result, the antenna may transmit a non-amplified backscattered modulation of the activation signal.

The means for modulating the activation signal may comprise means for modulating the activation signal via a binary phase shift keying modulator or via an on-off modulator. A switch may operate as an on-off modulator.

The means for determining whether oscillations are detected by the oscillation detector comprises: means for determining that oscillations are not detected by the oscillation detector; and the means for controlling the amplifier based on whether oscillations are detected by the oscillation detector may comprise: means for controlling the amplifier to maintain a bias of the amplifier.

The apparatus may comprise: means for controlling the first switch to connect directly or indirectly the amplifier to the antenna; and means for modulating the activation signal.

As a result, the antenna may transmit an amplified backscatter modulation of the activation signal.

The means for modulating the activation signal may comprise means for modulating the activation signal via a binary phase shift keying modulator or via an on-off modulator. The amplifier may operate as an on-off modulator by turning off and alternatively turning on the amplifier.

The means for determining that oscillations are detected by the oscillation detector may comprise: means for determining that a power of oscillations above an oscillation power threshold is detected by the oscillation detector.

The apparatus may comprise: an activation signal detector configured to detect an activation signal; a second switch configured to connect directly or indirectly the antenna to the activation signal detector or connect directly or indirectly the antenna to the amplifier; means for controlling the second switch to connect directly or indirectly the antenna to the activation signal detector; and means for controlling the amplifier based on whether an activation signal is detected by the activation signal detector.

The means for controlling the amplifier based on whether an activation signal is detected by the activation signal detector may comprise: means for determining that an activation signal is detected by activation signal detector; and means for determining a bias of the amplifier based on the activation signal.

The means for determining that an activation signal is detected by activation signal detector may comprise: means for determining that a power of the activation signal above an activation signal power threshold is detected by the activation signal detector; and the means for determining a bias of the amplifier based on the activation signal may comprise: means for determining a bias of the amplifier based on the power of the activation signal.

The apparatus may comprise: a modulator configured to modulate the activation signal; and the first switch may be configured to connect indirectly the amplifier to the antenna via the modulator.

The modulator may be a phase modulator.

The modulator may be a binary phase shift keying modulator.

The apparatus may comprise: a second switch configured to connect directly or indirectly the amplifier to a first path of the modulator or connect directly or indirectly the amplifier to a second path of the modulator.

The apparatus may comprise: a filter configured to filter a frequency fact of the activation signal and pass a frequency fₙₐₜ of the amplifier; wherein the first switch is configured to connect directly or indirectly the amplifier to the oscillations detector via the filter.

The amplifier may be configured to provide maximum gain at a frequency fₙₐₜ.

A difference between the frequency fₙₐₜ and the frequency fact may be greater than 2 MHz to allow a filter to attenuate the frequency fact whilst passing the frequency fₙₐₜ.

The apparatus may comprise: means for controlling the amplifier to turn on and alternatively turn off the amplifier to modulate the activation signal.

The amplifier may be a reflection amplifier.

The amplifier may be a single port reflection amplifier.

The apparatus may be an Internet of things device.

The apparatus may be an ambient Internet of things device.

The apparatus may be an ambient Internet of things device type 2A ambient Internet of things device.

According to an aspect there is provided a method performed by an apparatus comprising: an antenna configured to receive an activation signal; an amplifier configured to amplify the activation signal; an oscillation detector configured to detect oscillations and a first switch configured to connect directly or indirectly the amplifier to the antenna or connect directly or indirectly the amplifier to the oscillation detector, the method comprising: controlling the first switch to connect directly or indirectly the amplifier to the oscillation detector or to connect directly or indirectly the amplifier to the antenna; determining whether oscillations are detected by the oscillation detector; and controlling the amplifier based on whether oscillations are detected by the oscillation detector.

The amplifier may be turned on.

The determining whether oscillations are detected by the oscillation detector may comprise: determining that oscillations are detected by the oscillation detector; and controlling the amplifier based on whether oscillations are detected by the oscillation detector comprises: determining that a bias of the amplifier is above a minimum bias; and controlling the amplifier to reduce the bias of the amplifier.

The determining whether oscillations are detected by the oscillation detector may comprise: determining that oscillations are detected by the oscillation detector; and controlling the amplifier based on whether oscillations are detected by the oscillation detector may comprise: determining that a bias of the amplifier is equal to a minimum bias; and controlling the amplifier to turn off the amplifier.

The method may comprise: modulating the activation signal.

As a result, the antenna may transmit a non-amplified backscattered modulation of the activation signal.

The modulating the activation signal may comprise modulating the activation signal via a binary phase shift keying modulator or via an on-off modulator. A switch may operate as an on-off modulator.

The determining whether oscillations are detected by the oscillation detector may comprise: determining that oscillations are not detected by the oscillation detector; and the controlling the amplifier based on whether oscillations are detected by the oscillation detector may comprise: controlling the amplifier to maintain a bias of the amplifier.

The method may comprise: controlling the first switch to connect directly or indirectly the amplifier to the antenna; and modulating the activation signal.

As a result, the antenna may transmit an amplified backscatter modulation of the activation signal.

The modulating the activation signal may comprise modulating the activation signal via a binary phase shift keying modulator or via an on-off modulator. The amplifier may operate as an on-off modulator by turning off and alternatively turning on the amplifier.

The determining that oscillations are detected by the oscillation detector may comprise: determining that a power of oscillations above an oscillation power threshold is detected by the oscillation detector.

The apparatus may comprise: an activation signal detector configured to detect an activation signal; a second switch configured to connect directly or indirectly the antenna to the activation signal detector or connect directly or indirectly the antenna to the amplifier; and the method may comprise controlling the second switch to connect directly or indirectly the antenna to the activation signal detector; and controlling the amplifier based on whether an activation signal is detected by the activation signal detector.

The controlling the amplifier based on whether an activation signal is detected by the activation signal detector may comprise: determining that an activation signal is detected by activation signal detector; and determining a bias of the amplifier based on the power of the activation signal.

The amplifier based on the activation signal.

The determining that an activation signal is detected by activation signal detector may comprise: determining that a power of the activation signal above an activation signal power threshold is detected by the activation signal detector; and the determining a bias of the amplifier based on the activation signal may comprise: determining a bias of the apparatus may comprise: a modulator configured to modulate the activation signal; and the first switch may be configured to connect indirectly the amplifier to the antenna via the modulator.

The modulator may be a phase modulator.

The modulator may be a binary phase shift keying modulator.

The apparatus may comprise: a second switch configured to connect directly or indirectly the amplifier to a first path of the modulator or connect directly or indirectly the amplifier to a second path of the modulator.

The apparatus may comprise: a filter configured to filter a frequency fact of the activation signal and pass a frequency fₙₐₜ of the amplifier; wherein the first switch is configured to connect directly or indirectly the amplifier to the oscillations detector via the filter.

The amplifier may be configured to provide maximum gain at a frequency fₙₐₜ.

A difference between the frequency fₙₐₜ and the frequency fact may be greater than 2 MHz to allow a filter to attenuate the frequency fact whilst passing the frequency fₙₐₜ.

The apparatus may comprise: means for controlling the amplifier to turn on and alternatively turn off the amplifier to modulate the activation signal.

The amplifier may be a reflection amplifier.

The amplifier may be a single port reflection amplifier.

The apparatus may be an Internet of things device.

The apparatus may be an ambient Internet of things device.

The apparatus may be an ambient Internet of things device type 2A ambient Internet of things device.

According to an aspect there is provided an apparatus comprising an antenna configured to receive an activation signal; an amplifier configured to amplify the activation signal; an oscillation detector configured to detect oscillations and a first switch configured to connect directly or indirectly the amplifier to the antenna or connect directly or indirectly the amplifier to the oscillation detector, at least one processor and at least one memory storing instructions that, when executed by the at least one processor, cause the apparatus at least to perform: controlling the first switch to connect directly or indirectly the amplifier to the oscillation detector or to connect directly or indirectly the amplifier to the antenna; determining whether oscillations are detected by the oscillation detector; and controlling the amplifier based on whether oscillations are detected by the oscillation detector.

According to an aspect there is provided an apparatus comprising an antenna configured to receive an activation signal; an amplifier configured to amplify the activation signal; an oscillation detector configured to detect oscillations and a first switch configured to connect directly or indirectly the amplifier to the antenna or connect directly or indirectly the amplifier to the oscillation detector, and circuitry configured to perform: controlling the first switch to connect directly or indirectly the amplifier to the oscillation detector or to connect directly or indirectly the amplifier to the antenna; determining whether oscillations are detected by the oscillation detector; and controlling the amplifier based on whether oscillations are detected by the oscillation detector.

According to an aspect there is provided a computer program comprising computer executable code which when run on at least one processor is configured to perform: controlling a first switch to connect directly or indirectly an amplifier to an oscillation detector or to connect directly or indirectly the amplifier to an antenna; determining whether oscillations are detected by the oscillation detector; and controlling the amplifier based on whether oscillations are detected by the oscillation detector.

According to an aspect, there is provided a computer readable medium comprising program instructions stored thereon for performing at least one of the above methods.

According to an aspect, there is provided a non-transitory computer readable medium comprising program instructions stored thereon for performing at least one of the above methods.

According to an aspect, there is provided a non-volatile tangible memory medium comprising program instructions stored thereon for performing at least one of the above methods.

In the above, many different aspects have been described. It should be appreciated that further aspects may be provided by the combination of any two or more of the aspects described above.

Various other aspects are also described in the following detailed description and in the attached claims.

### LIST OF ABBREVIATIONS

AF: Application Function
AIoT: Ambient Internet of Things
AMF: Access and Mobility Management Function
BPSK: Binary Phase Shift Keying
BS: Base Station
CU: Centralized Unit
DL: Downlink
DU: Distributed Unit
gNB: gNodeB
IoT: Internet of Things
LTE: Long Term Evolution
MS: Mobile Station
MTC: Machine Type Communication
NEF: Network Exposure Function
NF: Network Function
NR: New radio
NRF: Network Repository Function
OOK: On Off Keying
RAM: Random Access Memory
(R)AN: (Radio) Access Network
ROM: Read Only Memory
SMF: Session Management Function
SNR: Signal to Noise Ration
UE: User Equipment
4G: 4th Generation
5G: 5th Generation
5GC: 5G Core network
5GS: 5G System
6G: 6th Generation

### BRIEF DESCRIPTION OF THE FIGURES

Embodiments will now be described, by way of example only, with reference to the accompanying Figures in which:

FIG. 1 shows a schematic representation of an example 5G system;

FIG. 2 shows a schematic representation of an example control apparatus;

FIG. 3 shows a schematic representation of an example user equipment;

FIG. 4 shows a schematic representation of an example activator user equipment, an ambient Internet of things device and a reader user equipment;

FIG. 5 shows a schematic representation of an example ambient Internet of things device comprising a reflection amplifier, a binary phase shift keying modulator and an antenna;

FIG. 6a and FIG. 6b shows a schematic representation of an example ambient Internet of things device according to a first implementation and a block diagram of a method of managing such ambient Internet of things device;

FIG. 7 shows a graphical representation of an example frequency response of a reflection amplifier;

FIG. 8a and FIG. 8b show a schematic representation of an example ambient Internet of things device according to a second implementation and a block diagram of a method of managing the ambient Internet of things device;

FIG. 9 shows a block diagram of a method for managing an ambient Internet of things device; and

FIG. 10 shows a schematic representation of a non-volatile memory medium storing instructions which when executed by a processor allow a processor to perform one or more of the steps of the method of FIG. 9.

### DETAILED DESCRIPTION OF THE FIGURES

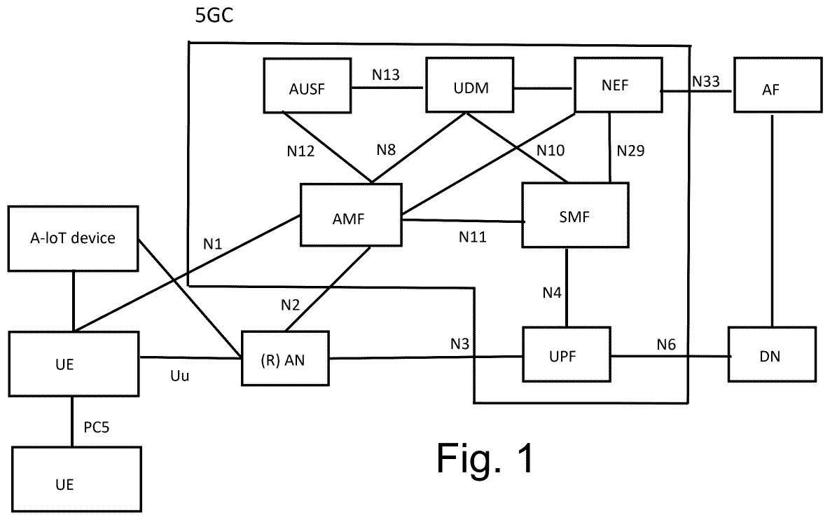

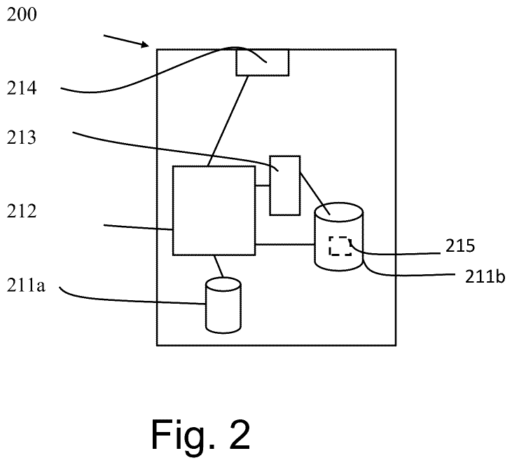

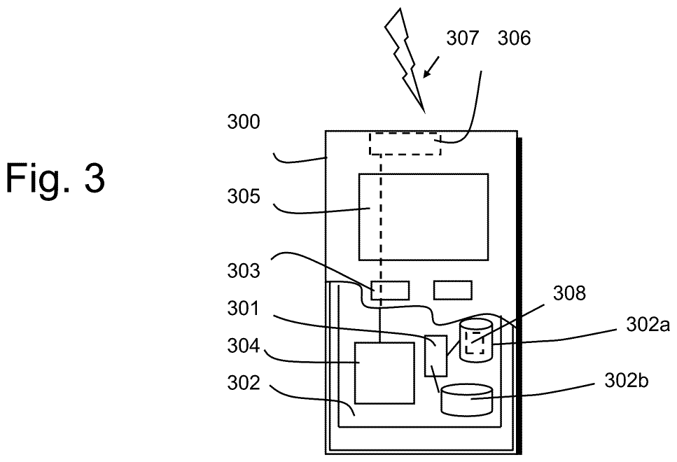

In the following certain embodiments are explained with reference to mobile communication devices capable of communication via a wireless cellular system and mobile communication systems serving such mobile communication devices. Before explaining in detail the exemplifying embodiments, certain general principles of a wireless communication system, access systems thereof, and mobile communication devices are briefly explained with reference to FIG. 1, FIG. 2 and FIG. 3 to assist in understanding the technology underlying the described examples.

FIG. 1 shows a schematic representation of an example 5G system (5GS). The 5GS may comprise Internet of things (IoT) devices, user equipment (UEs), a (radio) access network ((R) AN), a 5G core network (5GC), one or more application functions (AF) and one or more data networks (DN).

The IoT devices may comprise ambient IoT (AIoT) devices. An AIoT device may be configured to measure ambient conditions, such as location, temperature, pressure, noise, light or other ambient conditions. An AIoT device may comprise a sensor. An AIoT device may comprise static memory with a (unique) identifier number or programmable memory with a (unique) identifier number and application-specific information.

The UEs may comprise activator UEs, reader UEs or activator and reader UEs. An activator UE may be configured to transmit an activation signal to an AIoT device to trigger the AIoT device to transmit a response signal to a reader UE. A reader UE may be configured to receive a response signal from an AIoT device and to transmit a report signal to the 5G (R)AN.

In this disclosure, the expressions “activation signal”, “illumination signal” and “incident signal” may be used interchangeably.

In this disclosure, the expressions “response signal”, “backscattered signal” or “reflected signal” may be used interchangeably.

The 5G (R)AN may comprise one or more gNodeBs (gNBs). The gNodeBs may comprise one or more gNB distributed unit functions connected to one or more gNB centralized unit functions.

The gNodeBs may comprise activator gNodeBs, reader gNodeBs or activator and reader gNodeBs.

The 5GC may comprise an access and mobility management function (AMF), a session management function (SMF), an authentication server function (AUSF), a user data management (UDM), a user plane function (UPF), a network exposure function (NEF).

FIG. 2 illustrates an example of a control apparatus 200 for controlling a function of the (R)AN or the 5GC as illustrated on FIG. 1. The control apparatus may comprise at least one random access memory (RAM) 211a, at least on read only memory (ROM) 211b, at least one processor 212, 213 and an input/output interface 214. The at least one processor 212, 213 may be coupled to the RAM 211a and the ROM 211b. The at least one processor 212, 213 may be configured to execute an appropriate software code 215. The software code 215 may for example allow to perform one or more steps to perform one or more of the present aspects. The software code 215 may be stored in the ROM 211b. The control apparatus 200 may be interconnected with another control apparatus 200 controlling another function of the 5G (R)AN or the 5GC. In some embodiments, each function of the (R)AN or the 5GC comprises a control apparatus 200. In alternative embodiments, two or more functions of the (R)AN or the 5GC may share a control apparatus.

FIG. 3 illustrates an example of a user equipment 300, such as the terminal illustrated on FIG. 1. The UE 300 may be provided by any device capable of sending and receiving radio signals. Non-limiting examples comprise a user equipment, a mobile station (MS) or mobile device such as a mobile phone or what is known as a ‘smart phone’, a computer provided with a wireless interface card or other wireless interface facility (e.g., USB dongle), a personal data assistant (PDA) or a tablet provided with wireless communication capabilities, a machine-type communications (MTC) device, a Cellular Internet of things (CIoT) device or any combinations of these or the like. The UE 300 may provide, for example, communication of data for carrying communications. The communications may be one or more of voice, electronic mail (email), text message, multimedia, data, machine data and so on.

The UE 300 may receive signals over an air or radio interface 307 via appropriate apparatus for receiving and may transmit signals via appropriate apparatus for transmitting radio signals. In FIG. 3 transceiver apparatus is designated schematically by block 306. The transceiver apparatus 306 may be provided for example by means of a radio part and associated antenna arrangement. The antenna arrangement may be arranged internally or externally to the mobile device.

The UE 300 may be provided with at least one processor 301, at least one memory ROM 302a, at least one RAM 302b and other possible components 303 for use in software and hardware aided execution of tasks it is designed to perform, including control of access to and communications with access systems and other communication devices. The at least one processor 301 is coupled to the RAM 302b and the ROM 302a. The at least one processor 301 may be configured to execute an appropriate software code 308. The software code 308 may for example allow to perform one or more of the present aspects. The software code 308 may be stored in the ROM 302a.

The processor, storage and other relevant control apparatus can be provided on an appropriate circuit board and/or in chipsets. This feature is denoted by reference 304. The device may optionally have a user interface such as keypad 305, touch sensitive screen or pad, combinations thereof or the like. Optionally one or more of a display, a speaker and a microphone may be provided depending on the type of the device.

The ambient Internet of things (AIoT) aims to fulfil unmet market requirements in the Internet of Things (IoT) domain such as deployment in extreme operational conditions (e.g., high pressure, extremely high/low temperature), maintenance-free devices (e.g., no need for the device battery replacement) and devices with ultra-low complexity, very small device size/form factor (e.g., thickness of mm), longer life cycle, etc.

The AIoT relies on ultra-low complexity devices with ultra-low power consumption for the very-low end IoT applications. An AIoT device is an IoT device powered by energy harvesting, being either battery-less or with limited energy storage capability (e.g., using a capacitor). The energy may be provided through the harvesting of radio waves, light, motion, heat, or any other suitable power source.

AIoT devices may comprise different types.

AIoT device 1: ˜1 μW peak power consumption, has energy storage, initial sampling frequency offset (SFO) up to 10× ppm, neither downlink (DL) nor uplink (UL) amplification in the AIoT device. The AIoT device's UL transmission is backscattered on a carrier wave provided externally.

AIoT device 2a: ≤a few hundred W peak power consumption, has energy storage, initial SFO up to 10× ppm, both DL and/or UL amplification in the device. The AIoT device's UL transmission is backscattered on a carrier wave provided externally.

AIoT device 2b: ≤a few hundred μW peak power consumption, has energy storage, initial SFO up to 10× ppm, both DL and/or UL amplification in the device. The AIoT device's UL transmission is generated internally by the AIoT device.

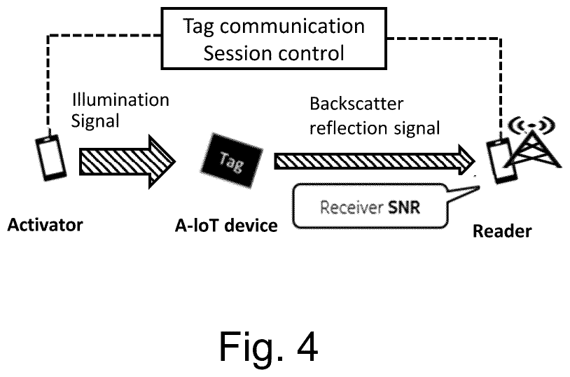

FIG. 4 shows a schematic representation of an activator UE, an AIoT device and a reader UE. The AIoT device may comprise an AIoT device type 2a AIoT device.

It will be understood that the activator UE may be replaced by an activator gNB and/or the reader UE may be replaced by a reader gNB.

An AIoT device type 2a AIoT device may implement a binary phase shift keying (BPSK) modulation of the activation signal to transmit the response signal. The BPSK modulation may be performed using a BPSK modulator comprising a switch, a first passive load (e.g., phase equal to 0 degree) and a second passive load (e.g., phase equal to 90 degrees). The BPSK modulation may attenuate the activation signal and therefore the signal to noise ratio of the response signal measured by the reader UE may be reduced.

An AIoT device type 2a AIoT device may implement amplification of the activation signal to transmit the response signal. The amplification may be performed using a reflection amplifier (e.g., a low power reflection amplifier). The reflection amplifier may be a single port reflection amplifier. The reflection amplifier may be a sub-biased oscillator that operates with low current (micro amp to milliamp current consumption). The reflection amplifier may present a negative resistance. The negative resistance may translate into a reflection gain. The reflection gain may be adjusted so that the signal to noise ratio of the response signal measured by the reader UE may be increased.

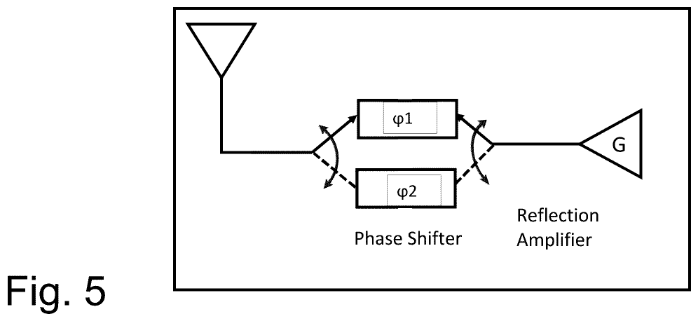

FIG. 5 shows a schematic representation of AIoT device type 2a AIoT device comprising a reflection amplifier, a BPSK modulator and an antenna.

A potential problem with the reflection amplifier may be stability. When a high-power activation signal is present at (e.g., received by) the reflection amplifier, the reflection amplifier may become unstable and start oscillating. This may result in interference compromising the response signal received by the reader UE.

One or more aspect of this disclosure provides a mechanism for managing an AIoT device (e.g., AIoT device type 2A AIoT device) to address the above problem (e.g., detect and suppress oscillations generated by the reflection amplifier).

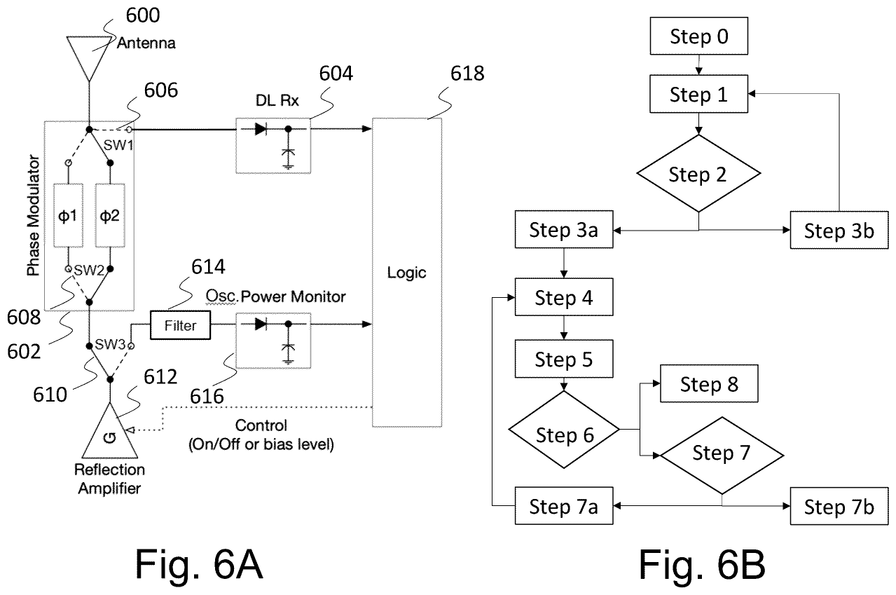

FIG. 6a and FIG. 6b shows a schematic representation of an example AIoT device according to a first implementation (e.g., binary phase shift keying modulation) and a block diagram of a method of managing such AIoT device.

The AIoT device may comprise an antenna 600. The antenna 600 configured to receiving an activation signal. The activation signal may be conveyed on a frequency fact.

The AIoT device may comprise a modulator 602. The modulator 602 may be configured to modulate the activation signal to transmit a response signal. The modulator 602 may comprise a phase modulator. The modulator 602 may be comprise a first phase path and a second phase path. The first path may comprise a first passive load with a first phase (e.g., 0 degree). The second path may comprise a second passive load with a second phase (e.g., 90 degrees). The modulator 602 may comprise a BPSK modulator.

The AIoT device may comprise an activation signal detector 604. The activation signal detector 604 may be configured to detect the activation signal. For example, the activation signal detector 604 may be configured to detect whether a power of the activation signal is above an activation signal power threshold. The activation signal detector 604 may comprise a diode and a capacitor. The activation signal detector 604 may be part of receiver circuitry.

In this disclosure, the expressions “activation signal detector”, “activation signal power detector”, “activation signal monitor”, “activation signal power monitor” or “downlink receiver (DL RX)” may be used interchangeably.

The AIoT device may comprise a switch SW1 606. The switch SW1 606 may be configured to connect the antenna 600 to the first path of the modulator 602, to connect the antenna 600 to the second path of the modulator 602 or alternatively to connect the antenna 600 to the activation signal detector 604.

The AIoT device may comprise a switch SW2 608. The switch SW2 608 may be configured to connect a switch SW3 610 to the first path of the modulator 602 or alternatively to connect the switch SW3 610 to the second path of the modulator 602.

The AIoT device may comprise an amplifier 612. The amplifier 612 may be configured to amplify the activation signal. The amplifier 612 may comprise a reflection amplifier. The amplifier 612 may comprise a single port reflection amplifier. The amplifier 612 may be configured to provide a maximum gain at a frequency fₙₐₜ (e.g., if antenna 600 isolation provided by the switch 608, the switch SW2 and the switch SW3 is inadequate). The frequency fₙₐₜ may be different from the frequency fact of the activation signal. The difference (e.g., offset) between the frequency fₙₐₜ and the frequency fact may be greater than 2 MHz to allow a filter 614 to attenuate the frequency fact whilst passing the frequency fₙₐₜ. In this way, an oscillation detector 616 may measure the energy of oscillations and not the energy of the activation signal.

It will be understood that in some implementation the filter 614 may be omitted (e.g., if antenna 600 isolation provided by the switch 608, the switch SW2 and the switch SW3 is adequate).

In this disclosure, the expressions “reflection amplifier” or “reflection gain amplifier” may be used interchangeably.

The AIoT device may comprise a filter 614. The filter 614 may be configured to attenuate the frequency fact whilst passing the frequency fₙₐₜ. The filter 614 may comprise a low pass filter, a band pass filter or a high pass filter.

The AIoT device may comprise the switch SW3 610. The switch SW3 610 may be configured to connect the amplifier 612 to the switch SW2 608 or alternatively to connect the amplifier 612 to the filter 614.

The AIoT device may comprise an oscillation detector 616. The oscillation detector 616 may be configured to detect oscillations. For example, the oscillation detector 616 may be configured to detect a power of the oscillations above an oscillations power threshold. The oscillation detector 616 may comprise a diode, a capacitor and a level comparator (e.g., Schmitt trigger). It will be understood that the oscillation detector 616 may have another configuration.

In this disclosure, the expressions “oscillation detector”, “oscillation power detector”, “oscillation monitor” or “oscillation power monitor” may be used interchangeably.

The AIoT device may comprise logic 618 configured to control the operation of the AIoT device.

The switch SW1 606, the switch SW2 608 and the switch SW3 610 may each attenuate the activation signal by at least 20 dB and therefore may altogether attenuate the activation signal by at least 40 dB at the oscillation detector 616.

At step 0, the logic 618 may control the switch SW1 606 to connect the antenna 600 to the activation signal detector 604. The logic 618 may control the switch SW2 608 to connect the switch SW3 610 to the first path of the modulator 602 or alternatively to connect the switch SW3 610 to the second path of the modulator 602. The logic 618 may control the switch SW3 610 to connect the switch SW3 610 to the switch SW2 608. The logic 618 may control the amplifier to turn off the amplifier.

At step 1, the antenna 600 may receive the activation signal.

At step 2, the logic 618 may determine whether the activation signal is detected by the activation signal detector 604. For example, the logic 618 may determine whether a power of the activation signal above an activation signal power threshold is detected by the activation signal detector 604.

At step 3a, if the logic 618 determines that the activation signal is detected by the activation signal detector 604, the logic 618 may control the amplifier 612 to set the bias of the amplifier. For example, if the logic 618 determines that a power of the activation signal above an activation signal power threshold is detected by the activation signal detector 604, the logic 618 may control the amplifier 612 to turn on the amplifier 612. The logic 618 may control the amplifier 612 to set the bias of the amplifier based on the power of the activation signal. The operation goes to step 4. The bias of the amplifier may be constant or variable (e.g., power cycled).

At step 3b, if the logic 618 determines that the activation signal is not detected by the activation signal detector 604, the logic 618 may not control the amplifier 612 to turn on the amplifier 612. The logic 618 may not control the amplifier 612 to set the bias of the amplifier. For example, if the logic 618 determines that a power of the activation signal above an activation signal power threshold is not detected by the activation signal detector 604, the logic 618 may not control the amplifier 612 to turn on the amplifier 612. The logic 618 may not control the amplifier 612 to set the bias of the amplifier based on the power of the activation signal. The operation goes back to step 1.

At step 4, the logic 618 may control the amplifier 612 to turn on the amplifier 612. The logic 618 may control the switch SW1 606 to connect the antenna 600 to the first path of the modulator 602 and alternatively to connect the antenna 600 to the second path of the modulator 602. The logic 618 may control the switch SW2 608 to connect the switch SW3 610 to the first path of the modulator 602 and alternatively to connect the switch SW3 610 to the second path of the modulator 602. The logic 618 may control the switch SW3 610 to connect the switch SW3 610 to the switch SW2 608. In this way, the logic 618 ensures that the amplifier 612 is exposed to the first path and alternatively the second path. If a high-power activation signal is received by the amplifier 612, the amplifier 612 may become unstable and may start oscillating with oscillations at the frequency fact.

At step 5, the logic 618 may control the switch SW1 606 to connect the antenna 600 to the first path of the modulator 602 or alternatively to connect the antenna 600 to the second path of the modulator 602. The logic 618 may control the switch SW2 608 to connect the switch SW3 610 to the second path of the modulator 602 or alternatively to connect the switch SW2 608 to the first path of the modulator 602 (opposite path of the switch SW1 606 to obtain 20 dB isolation between the antenna 602 and the amplifier 612). Alternatively, the logic 618 may control the switch SW1 606 to connect the antenna 600 to the activation signal detector 604 (to obtain 20 dB isolation between the antenna 602 and the amplifier 612).

The logic 618 may control the switch SW3 610 to connect the amplifier 612 to the filter 614 (to obtain a further 20 dB isolation between the antenna 602 and the amplifier 612). If a high-power activation signal was received by the amplifier 612, causing the amplifier 612 to become unstable, the amplifier 612 may remain unstable and may continue oscillating with oscillations now at the frequency fₙₐₜ.

At step 6, the logic 618 may determine whether oscillations are detected by the oscillation detector 616. For example, the logic 618 determines whether a power of the oscillations above the oscillation power threshold is detected by the oscillation detector 616.

At step 7, if the logic 618 determines that oscillations are detected by the oscillation detector 616, the logic 618 may determine whether the bias of the amplifier 612 is above a minimum bias. For example, if the logic 618 determines that a power of the oscillations above the oscillation power threshold is detected by the oscillation detector 616, the logic 618 may determine whether the bias of the amplifier 612 is above a minimum bias.

At step 7a, if the logic 618 determines that the bias of the amplifier 612 is above the minimum bias, the logic 618 may reduce the bias of the amplifier 612. The operation goes back to step 4.

At step 7b, if the logic 618 determines that the bias of the amplifier 612 is equal to or below the minimum bias, the logic 618 may control the switch SW1 606 to connect the antenna 600 to the first path of the modulator 602 and alternatively to connect the antenna 600 to the second path of the modulator 602. The logic 618 may control the switch SW2 608 to connect the switch SW3 610 to the first path of the modulator 602 and alternatively to connect the switch SW3 610 to the second path of the modulator 602. The logic 618 may control the switch SW3 610 to connect the switch SW3 610 to the filter 612. In this way, the antenna 600 may transmit a non-amplified backscattered modulation of the activation signal. The logic 618 may control the amplifier 612 to turn off the amplifier. In this way, energy consumption may be reduced.

At step 8, if the logic 618 determines that oscillations are not detected by the oscillation detector 616, the logic 618 may maintain (e.g., keep) the bias of the amplifier 612. For example, if the logic 618 determines that a power of the oscillations above the oscillation power threshold is not detected by the oscillation detector 616, the logic 618 may maintain the bias of the amplifier 612. The logic 618 may control the switch SW1 606 to connect the antenna 600 to the first path of the modulator 602 and alternatively to connect the antenna 600 to the second path of the modulator 602. The logic 618 may control the switch SW2 608 to connect the switch SW3 610 to the first path of the modulator 602 and alternatively to connect the switch SW3 610 to the second path of the modulator 602. The logic 618 may control the switch SW3 610 to connect the switch SW3 610 to the switch SW2 608. In this way, the antenna 600 may transmit an amplified backscattered modulation of the activation signal.

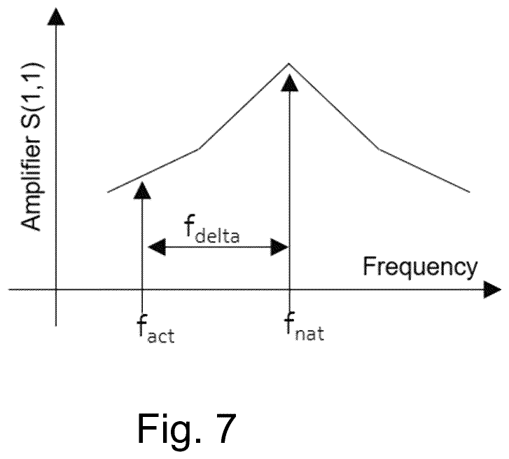

FIG. 7 shows a graphical representation of an example frequency response of the amplifier 612.

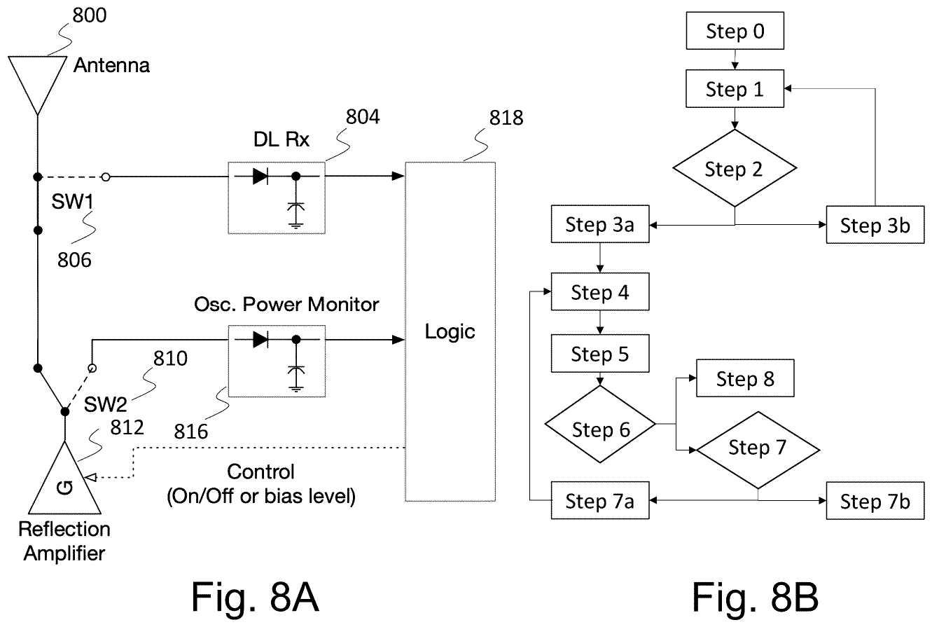

FIG. 8a and FIG. 8b shows a schematic representation of an example AIoT device according to a second implementation (e.g., on off keying (OOK) modulation) and a block diagram of a method of managing such AIoT device.

The AIoT device may comprise an antenna 800. The antenna 800 configured to receiving an activation signal. The activation signal may be conveyed on a frequency fact.

The AIoT device may comprise an activation signal detector 804. The activation signal detector 604 may be configured to detect the activation signal. For example, the activation signal detector 804 may be configured to detect whether a power of the activation signal is above an activation signal power threshold. The activation signal detector 804 may comprise a diode and a capacitor. The activation signal detector 804 may be part of receiver circuitry.

The AIoT device may comprise a switch SW1 806. The switch SW1 806 may be configured to connect the antenna 800 to a switch SW2 810 or alternatively to connect the antenna 800 to the activation signal detector 804.

The AIoT device may comprise an amplifier 812. The amplifier 812 may be configured to amplify the activation signal. The amplifier 812 may comprise a reflection amplifier. The amplifier 812 may comprise a single port reflection amplifier.

The AIoT device may comprise an oscillation detector 816. The oscillation detector 816 may be configured to detect oscillations. For example, the oscillation detector 816 may be configured to detect a power of the oscillations above an oscillations power threshold. The oscillation detector 816 may comprise a diode, a capacitor and a level comparator (e.g., Schmitt trigger). It will be understood that the oscillation detector 816 may have another configuration.

The AIoT device may comprise the switch SW2 810. The switch SW2 810 may be configured to connect the amplifier 812 to the switch SW1 806 or alternatively to connect the amplifier 812 to the oscillation detector 816.

The AIoT device may comprise logic 818 configured to control the operation of the AIoT device.

It will be understood that as for the embodiment of FIG. 6, a filter 814 may be connected to the oscillation power detector 816 or may be omitted.

At step 0, the logic 818 may control the switch SW1 806 to connect the antenna 802 to the activation signal detector 804. The logic 818 may control the switch SW2 810 to connect the amplifier 812 to the switch SW1 806. The logic 818 may control the amplifier 812 to turn off the amplifier 812.

At step 1, the antenna 800 may receive the activation signal.

At step 2, the logic 818 may determine whether the activation signal is detected by the activation signal detector 804. For example, the logic 818 may determine whether a power of the activation signal above an activation signal power threshold is detected by the activation signal detector 804.

At step 3a, if the logic 818 determines that the activation signal is detected by the activation signal detector 804, the logic 818 may control the switch SW1 806 to connect the antenna 800 to the switch SW2 810. The logic 818 may control the amplifier 812 to turn on and alternatively off the amplifier 812. In this way, the amplifier 812 may perform on off keying (OOK) modulation. The logic 818 may control the amplifier 812 to set the bias of the amplifier 812. For example, if the logic 818 determines that a power of the activation signal above an activation signal power threshold is detected by the activation signal detector 804, the logic 818 may control the amplifier 812 to turn on and alternatively off the amplifier 812. The logic 818 may control the amplifier 812 to set the bias of the amplifier based on the power of the activation signal. The operation goes to step 4. The bias of the amplifier may be constant or variable (e.g., power cycled).

At step 3b, if the logic 818 determines that the activation signal is not detected by the activation signal detector 804, the logic 818 may not control the amplifier 612 to turn on and alternatively off the amplifier 812. The logic 818 may not control the amplifier 812 to set the bias of the amplifier. For example, if the logic 818 determines that a power of the activation signal above an activation signal power threshold is not detected by the activation signal detector 804, the logic 818 may not control the amplifier 812 to turn on and alternatively off the amplifier 812. The logic 818 may not control the amplifier 812 to set the bias of the amplifier based on the power of the activation signal. The operation goes back to step 1.

At step 4, if a high-power activation signal is received by the amplifier 812, the amplifier 812 may become unstable and may start oscillating with oscillations at the frequency fact.

At step 5, the logic 818 may control the switch SW2 810 to connect the amplifier 812 to the oscillation power detector 816 (to obtain a 20 dB isolation between the antenna 802 and the amplifier 812) If a high-power activation signal was received by the amplifier 812 causing the amplifier 812 to become unstable, the amplifier 812 may remain unstable and may continue oscillating with oscillations at the frequency fact. The logic 818 may control the switch SW1 to connect to the activation signal detector 804 (to obtain a further 20 dB isolation between the antenna 802 and the amplifier 812).

At step 6, the logic 818 may determine whether oscillations are detected by the oscillation detector 816. For example, the logic 818 determines whether a power of the oscillations above the oscillation power threshold is detected by the oscillation detector 816.

At step 7, if the logic 818 determines that oscillations are detected by the oscillation detector 816, the logic 818 may determine whether the bias of the amplifier 812 is above a minimum bias. For example, if the logic 818 determines that a power of the oscillations above the oscillation power threshold is detected by the oscillation detector 816, the logic 818 may determine whether the bias of the amplifier 812 is above a minimum bias.

At step 7a, if the logic 818 determines that the bias of the amplifier 812 is above the minimum bias, the logic 818 may reduce the bias of the amplifier 812. The operation goes back to step 4.

At step 7b, if the logic 818 determines that the bias of the amplifier 812 is equal to the minimum bias, the logic 818 may control the switch SW1 806 to connect the antenna 800 to the switch SW2 810 and alternatively to connect the antenna 800 to the activation signal detector 804. In this way, the antenna 800 may transmit a non-amplified backscattered modulation of the activation signal. The logic 818 may control the switch SW2 810 to connect the amplifier 812 to the oscillation detector 814. The logic 818 may control the amplifier 812 to turn off the amplifier. In this way, energy consumption may be reduced.

At step 8, if the logic 618 determines that oscillations are not detected by the oscillation detector 816, the logic 618 may maintain (e.g., keep) the bias of the amplifier 812. For example, if the logic 818 determines that a power of the oscillations above the oscillation power threshold is not detected by the oscillation detector 816, the logic 818 may maintain the bias of the amplifier 812. The logic 818 may control the switch SW2 810 to connect the amplifier 812 to the switch SW1 806. In this way, the antenna 800 may transmit an amplified backscattered OOK modulation of the activation signal.

It will be understood that an AIoT device supporting both BPSK and OOK modulation can be realized by maintaining functionality of SW3 in FIG. 6 equal to that of SW2 in FIG. 8 and keeping SW2 in FIG. 6 at a fixed state for OOK modulation.

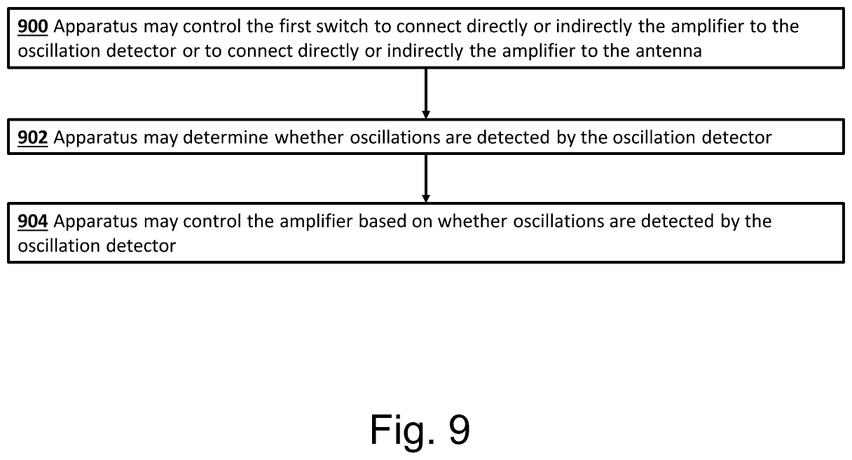

FIG. 9 shows a block diagram of a method for managing an AIoT device. The method may be performed by an apparatus (e.g., the AIoT device) comprising antenna configured to receive an activation signal; an amplifier configured to amplify the activation signal; an oscillation detector configured to detect oscillations; and a first switch configured to connect directly or indirectly the amplifier to the antenna or connect directly or indirectly the amplifier to the oscillation detector.

At step 900, an apparatus may control the first switch to connect directly or indirectly the amplifier to the oscillation detector or to connect directly or indirectly the amplifier to the antenna.

At step 902, the apparatus may determine whether oscillations are detected by the oscillation detector.

At step 904, the apparatus may control the amplifier based on whether oscillations are detected by the oscillation detector

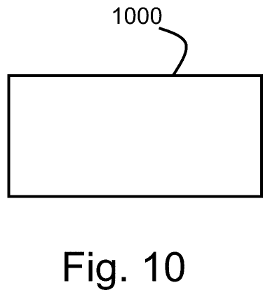

FIG. 10 shows a schematic representation of non-volatile memory media 1000 storing instructions which when executed by a processor allow the processor to perform one or more of the steps of the method of FIG. 9.

It is noted that while the above describes example embodiments, there are several variations and modifications which may be made to the disclosed solution without departing from the scope of the present invention.

It will be understood that although the above concepts have been discussed in the context of a 5GS, one or more of these concepts may be applied to other cellular or non-cellular systems.

The embodiments may thus vary within the scope of the attached claims. In general, some embodiments may be implemented in hardware or special purpose circuits, software, logic or any combination thereof. For example, some aspects may be implemented in hardware, while other aspects may be implemented in firmware or software which may be executed by a controller, microprocessor or other computing device, although embodiments are not limited thereto. While various embodiments may be illustrated and described as block diagrams, flow charts, or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

The embodiments may be implemented by computer software stored in a memory and executable by at least one data processor of the involved entities or by hardware, or by a combination of software and hardware. Further in this regard it should be noted that any procedures, e.g., as in FIG. 9, may represent program steps, or interconnected logic circuits, blocks and functions, or a combination of program steps and logic circuits, blocks and functions. The software may be stored on such physical media as memory chips, or memory blocks implemented within the processor, magnetic media such as hard disk or floppy disks, and optical media such as for example DVD and the data variants thereof, CD.

The memory may be of any type suitable to the local technical environment and may be implemented using any suitable data storage technology, such as semiconductor-based memory devices, magnetic memory devices and systems, optical memory devices and systems, fixed memory and removable memory. The data processors may be of any type suitable to the local technical environment, and may include one or more of general purpose computers, special purpose computers, microprocessors, digital signal processors (DSPs), application specific integrated circuits (ASIC), gate level circuits and processors based on multi-core processor architecture, as non-limiting examples.

Alternatively or additionally, some embodiments may be implemented using circuitry. The circuitry may be configured to perform one or more of the functions and/or method steps previously described. That circuitry may be provided in the base station and/or in the communications device.

As used in this application, the term “circuitry” may refer to one or more or all of the following:
(a) hardware-only circuit implementations (such as implementations in only analogue and/or digital circuitry);
(b) combinations of hardware circuits and software, such as:
   (i) a combination of analogue and/or digital hardware circuit(s) with software/firmware and
   (ii) any portions of hardware processor(s) with software (including digital signal processor(s)), software, and memory(ies) that work together to cause an apparatus, such as the communications device or base station to perform the various functions previously described; and
(c) hardware circuit(s) and or processor(s), such as a microprocessor(s) or a portion of a microprocessor(s), that requires software (e.g., firmware) for operation, but the software may not be present when it is not needed for operation.

This definition of circuitry applies to all uses of this term in this application, including in any claims. As a further example, as used in this application, the term circuitry also covers an implementation of merely a hardware circuit or processor (or multiple processors) or portion of a hardware circuit or processor and its (or their) accompanying software and/or firmware. The term circuitry also covers, for example integrated device.

The term “means” as used in the description and in the claims may refer to one or more individual elements configured to perform the corresponding recited functionality or functionalities, or it may refer to several elements that perform such functionality or functionalities. Furthermore, several functionalities recited in the claims may be performed by the same individual means or the same combination of means. For example, performing such functionality or functionalities may be caused in an apparatus by a processor that executes instructions stored in a memory of the apparatus.

The foregoing description has provided by way of exemplary and non-limiting examples a full and informative description of some embodiments However, various modifications and adaptations may become apparent to those skilled in the relevant arts in view of the foregoing description, when read in conjunction with the accompanying drawings and the appended claims. However, all such and similar modifications of the teachings will still fall within the scope as defined in the appended claims.

1. An apparatus comprising:
an antenna configured to receive an activation signal;
an amplifier configured to amplify the activation signal;
an oscillation detector configured to detect oscillations;
a first switch configured to connect directly or indirectly the amplifier to the antenna or connect directly or indirectly the amplifier to the oscillation detector;
at least one processor and at least one memory storing instructions that, when executed by the at least one processor, cause the apparatus at least to perform:
controlling the first switch to connect directly or indirectly the amplifier to the oscillation detector or to connect directly or indirectly the amplifier to the antenna;
determining whether oscillations are detected by the oscillation detector; and
controlling the amplifier based on whether oscillations are detected by the oscillation detector.

2. The apparatus of claim 1, wherein the determining whether oscillations are detected by the oscillation detector comprises:
determining that oscillations are detected by the oscillation detector; and
controlling the amplifier based on whether oscillations are detected by the oscillation detector comprises:
determining that a bias of the amplifier is above a minimum bias; and
controlling the amplifier to reduce the bias of the amplifier.

3. The apparatus of claim 1, wherein the determining whether oscillations are detected by the oscillation detector comprises:
determining that oscillations are detected by the oscillation detector; and
controlling the amplifier based on whether oscillations are detected by the oscillation detector comprises:
determining that a bias of the amplifier is equal to a minimum bias; and
controlling the amplifier to turn off the amplifier.

4. The apparatus of claim 3, wherein the at least one processor causes the apparatus to perform:
modulating the activation signal.

5. The apparatus of claim 1, wherein the determining whether oscillations are detected by the oscillation detector comprises:
determining that oscillations are not detected by the oscillation detector; and
controlling the amplifier based on whether oscillations are detected by the oscillation detector comprises:
controlling the amplifier to maintain a bias of the amplifier.

6. The apparatus of claim 5, wherein the at least one processor causes the apparatus to perform:
controlling the first switch to connect directly or indirectly the amplifier to the antenna; and
modulating the activation signal.

7. The apparatus of claim 2, wherein the determining that oscillations are detected by the oscillation detector comprises:
determining that a power of oscillations above an oscillation power threshold is detected by the oscillation detector.

8. The apparatus of claim 1, comprising:
an activation signal detector configured to detect an activation signal;
a second switch configured to connect directly or indirectly the antenna to the activation signal detector or connect directly or indirectly the antenna to the amplifier;
wherein the at least one processor causes the apparatus to perform:
controlling the second switch to connect directly or indirectly the antenna to the activation signal detector; and
controlling the amplifier based on whether an activation signal is detected by the activation signal detector.

9. The apparatus of claim 8, wherein the controlling the amplifier based on whether an activation signal is detected by the activation signal detector comprises:
determining that an activation signal is detected by activation signal detector; and
determining a bias of the amplifier based on the activation signal.

10. The apparatus of claim 8, wherein the determining that an activation signal is detected by activation signal detector comprises:
determining that a power of the activation signal above an activation signal power threshold is detected by the activation signal detector; and
determining a bias of the amplifier based on the activation signal comprises:
determining a bias of the amplifier based on the power of the activation signal.

11. The apparatus of claim 1, comprising:
a modulator configured to modulate the activation signal; and
wherein the first switch is configured to connect indirectly the amplifier to the antenna via the modulator.

12. The apparatus of claim 11, wherein the modulator is a phase modulator.

13. The apparatus of claim 12, wherein the modulator is a binary phase shift keying modulator.

14. The apparatus of claim 12, comprising:
a second switch configured to connect directly or indirectly the amplifier to a first path of the modulator or connect directly or indirectly the amplifier to a second path of the modulator.

15. The apparatus of claim 1, comprising:
a filter configured to filter a frequency fact of the activation signal and pass a frequency fₙₐₜ of the amplifier;
wherein the first switch is configured to connect directly or indirectly the amplifier to the oscillations detector via the filter.

16. The apparatus of claim 1, wherein the at least one processor causes the apparatus to perform:
controlling the amplifier to turn on and alternatively turn off the amplifier to modulate the activation signal.

17. The apparatus of claim 1, wherein the amplifier is a reflection amplifier.

18. The apparatus of claim 1, wherein the apparatus is an Internet of things device.

19. A method comprising:
receiving an activation signal by an antenna;
amplifying the activation signal by an amplifier;
determining whether oscillations are detected by an oscillation detector;
controlling a switch to connect directly or indirectly the amplifier to the oscillation detector or to connect directly or indirectly the amplifier to the antenna; and
controlling the amplifier based on whether oscillations are detected by the oscillation detector.

20. A non-transitory computer-readable storage medium comprising instructions stored thereon that, when executed by at least one processor, are configured to cause an apparatus to perform the method of claim 19.
